(19) United States
(12) Patent Application Publication
(10) Pub. No.: US 2013/0154109 A1
(43) Pub. Date: Jun. 20, 2013

(54) METHOD OF LOWERING CAPACITANCES OF CONDUCTIVE APERTURES AND AN INTERPOSER CAPABLE OF BEING REVERSE BIASED TO ACHIEVE REDUCED CAPACITANCE

(71) Applicants: Ramnath Venkatraman, San Jose, CA (US); John W. Osenbach, Kutztown, PA (US); Anwar Ali, San Jose, CA (US); Donald E. Hawk, King of Prussia, PA (US); Robert J. Madge, Redwood City, CA (US)

(72) Inventors: Ramnath Venkatraman, San Jose, CA (US); John W. Osenbach, Kutztown, PA (US); Anwar Ali, San Jose, CA (US); Donald E. Hawk, King of Prussia, PA (US); Robert J. Madge, Redwood City, CA (US)

(73) Assignee: LSI Corporation, Milpitas, CA (US)

(21) Appl. No.: 13/328,332

(22) Filed: Dec. 16, 2011

(51) Int. Cl. H01L 23/48; H01L 21/22; H01L 21/02

(52) U.S. Cl. 257/774; 438/466; 257/734; 438/510; 257/E21.002; 257/E23.01; 257/E23.011; 257/E21.135

(57) ABSTRACT

The disclosure provides an interposer with conductive paths, a three-dimensional integrated circuit (3D IC), a method of reducing capacitance associated with conductive paths in an interposer and a method of manufacturing an interposer. In one embodiment the interposer includes: (1) a semiconductor substrate that is doped with a dopant, (2) conductive paths located within said semiconductor substrate and configured to provide electrical routes therethrough and (3) an ohmic contact region located within said semiconductor substrate and configured to receive a back bias voltage.

### BACKGROUND

Three-dimensional ICs provide a path to continue CMOS scaling, especially for certain technologies (e.g., memories and analog) where scaling has become increasingly difficult to achieve. The fabrication of 3D ICs involves stacking of one or more dies on each other and connecting the stacked dies using conductive paths, such as conductive apertures. For some conductive apertures, tungsten has been used as the conductor but other conductive apertures are processed using copper metallization.

Various integration schemes have been used in the art to incorporate conductive apertures with the stacked dies. In the 3D integration schemes, the conductive apertures are placed in relative proximity to active metal-oxide-semiconductor (MOS) devices on a die. This placing of the conductive apertures requires complex processing steps of the die as well as accounting for complex interactions between the mechanical stress field associated with the conductive apertures and the active devices.

Another approach for using 3D conductive apertures, often referred to as “2.5D,” uses an interposer that is attached as an intermediate connector to two or more stacked die. The interposer is a semiconductor substrate with conductive paths, such as conductive apertures, for providing electrical connections between the stacked die. In one embodiment, the interposer may be processed using a semiconductor, such as standard silicon and is typically passive (i.e., no active components attached). The conductive paths within the interposer may be processed similarly using a metallization process, such as copper metallization, as discussed above with the various 3D integration schemes.

### SUMMARY

In one embodiment, an interposer capable of being reverse biased is disclosed. The interposer includes: (1) a semiconductor substrate that is doped with a dopant, (2) conductive paths located within said semiconductor substrate and configured to provide electrical routes therethrough and (3) an ohmic contact region located on or within said semiconductor substrate and configured to receive a back bias voltage.

In another embodiment the disclosure provides a method of reducing capacitance associated with conductive paths of an interposer capable of being reverse biased. The method includes: (1) generating a back bias voltage to reverse bias a semiconductor substrate of the interposer to increase a depletion region therein that is associated with the conductive paths and (2) applying the back bias voltage to the interposer through an electrical contact.

In still another embodiment, the disclosure provides a 3D IC. The 3D IC includes: (1) a first die, (2) a second die and an interposer located between the first and the second die and configured to connect the first die to the second die, the interposer adapted to be reverse biased whenever a back bias voltage source is applied thereto. The interposer having a semiconductor substrate that is doped with a dopant, conductive paths located within the semiconductor substrate and configured to provide electrical routes through the semiconductor substrate to connect the first die to the second die and an ohmic contact region located within the semiconductor substrate and adapted to be coupled to a back bias voltage souce.

In yet another embodiment, the disclosure provides a method of manufacturing an interposer capable of being reversed bias. The method includes: (1) providing a doped semiconductor substrate of an interposer, wherein the doped semiconductor substrate includes at least one conductive path, (2) heavily doping a region of the doped semiconductor substrate to form an ohmic contact region and (3) forming an electrical contact near a surface of the doped semiconductor substrate in electrical contact with the ohmic contact region.

### BRIEF DESCRIPTION

Reference is now made to the following descriptions taken in conjunction with the accompanying drawings, in which:

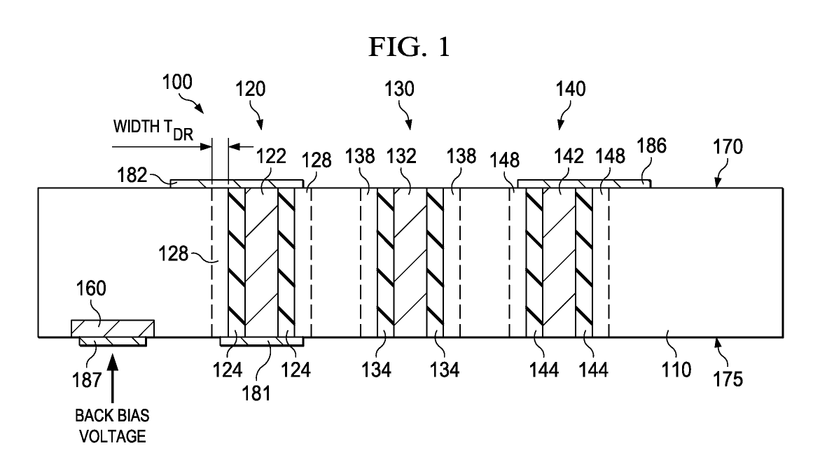

FIG. 1 illustrates a side view of an embodiment of an interposer capable of being reverse biased, constructed according to the principles of the disclosure;

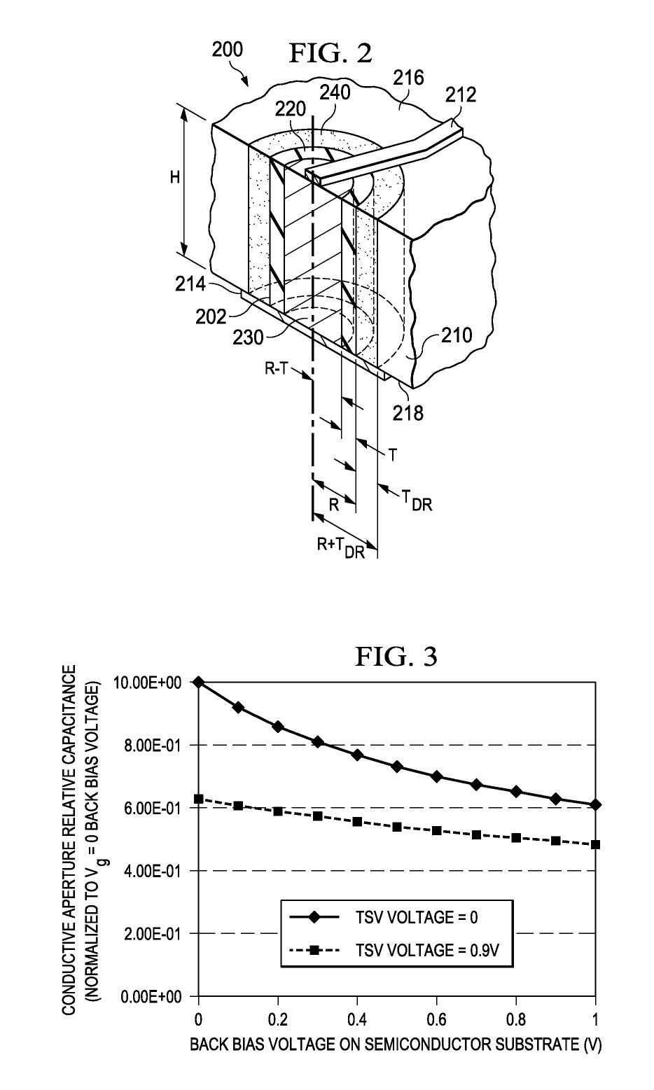

FIG. 2 illustrates a perspective diagram of an embodiment of a conductive aperture;

FIG. 3 illustrates a graph representing the reduction of relative capacitance associated with conductive paths when employing a back bias voltage according to the principles of the disclosure;

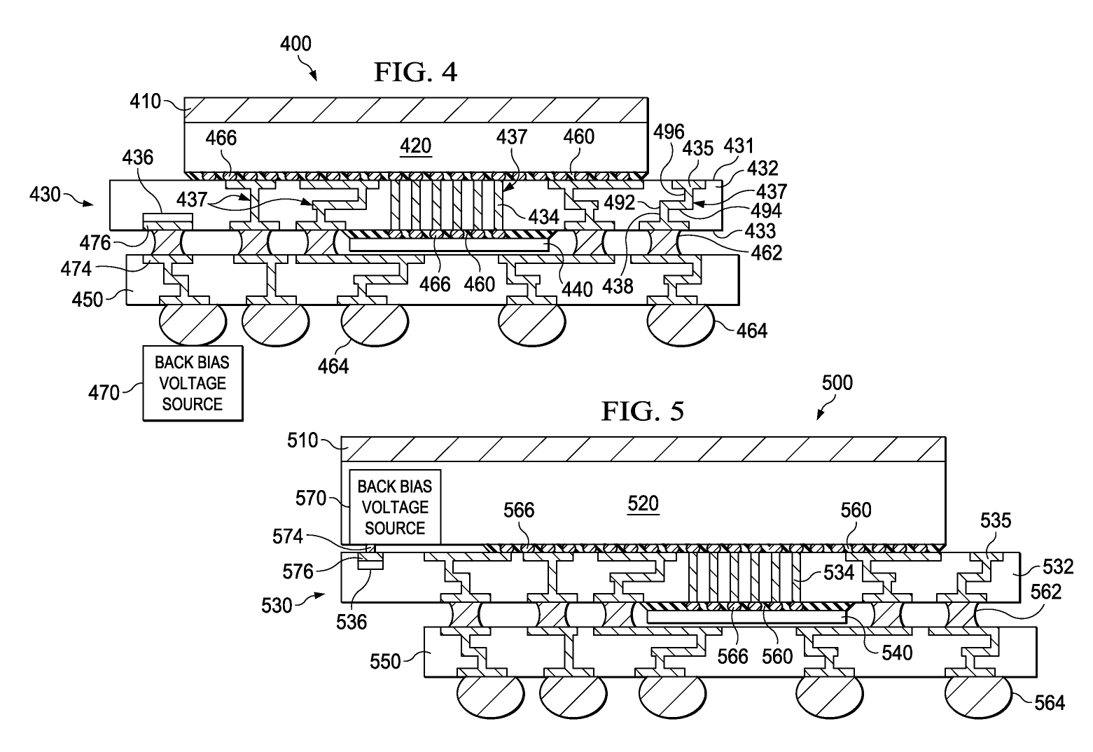

FIG. 4 illustrates a cross-section view of an embodiment of a 3D IC constructed according to the principles of the disclosure;

FIG. 5 illustrates a cross-section view of another embodiment of a 3D IC constructed according to the principles of the disclosure;

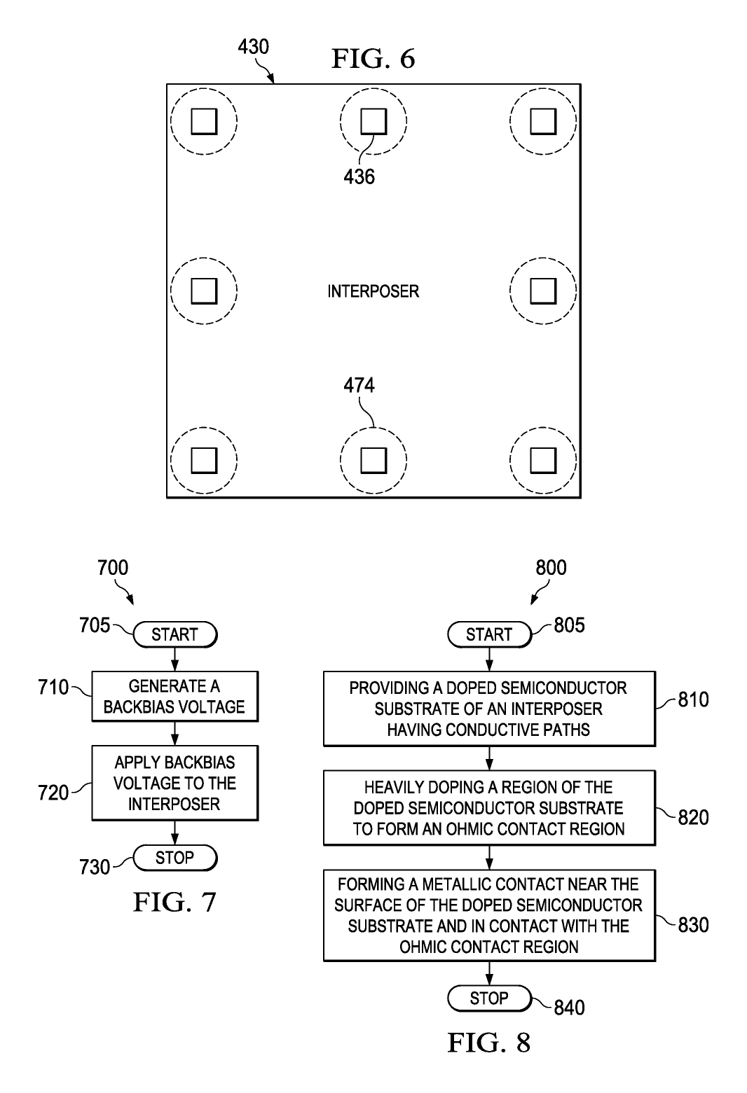

FIG. 6 illustrates a top view of an embodiment of an interposer capable of being reverse biased, constructed according to the principles of the disclosure;

FIG. 7 illustrates a flow diagram of a method of reducing capacitance associated with conductive paths of an interposer capable of being reverse biased, carried out according to the principles of the disclosure; and

FIG. 8 illustrates a flow diagram of a method of manufacturing an interposer capable of being reverse biased, carried out according to the principles of the disclosure.

### DETAILED DESCRIPTION

In addition to providing a path for communicating signals between or among two or more die, the conductive paths in an interposer can also be used to make other electrical connections, such as a connection for 10 signals between a die and a package or between a die and an external board. The 10 signals that traverse the conductive paths in these other electrical connections often include high frequency signals, such as, signals from a Serdes IP block. An interposer and the included conductive paths, therefore, can provide electrical connections for dies directly connected to the interposer and for other components of, for example, a 3D IC.

The disclosure recognizes that the parasitic characteristics of a conductive path in an interposer may be extremely important due to, for example, the high frequency signals that can pass therethrough. As such, the disclosure recognizes the advantages of reducing the capacitance associated with a conductive path. Accordingly, the disclosure provides a technique to reduce the parasitic capacitance of conductive paths in an interposer. As disclosed herein, the semiconductor material of an interposer capable of being reverse biased is electrically biased to modulate the size of a depletion region in the semiconductor material associated with a respective conductive path and thus the capacitance to which a signal passing therethrough is subjected. Accordingly, a significant reduction in parasitic capacitance of conductive paths can be obtained and may be reduced to as small as possible.

FIG. 1 illustrates a diagram of an embodiment of an interposer capable of being reverse biased, 100 constructed according to the principles of the disclosure. The interposer 100 is configured to be an intermediate connector for electrically and mechanically coupling components, such as two or more dies in a 3D IC. The interposer 100 includes a semiconductor substrate 110, multiple conductive paths denoted as 120, 130 and 140 and an ohmic contact region 160. The semiconductor substrate 110 has a first major surface 170 and a second major surface 175. Additionally, the interposer includes metallic contacts 181, 182 and 186, located on the first and the second major surfaces 170, 175.

The metallic contacts 181, 182 and 186, are conventional interfaces that provide an area for mechanical and conductive connections. The metallic contacts 181, 182 and 186, illustrated in FIG. 1 are located on the major surfaces of the semiconductor substrate 110 to provide a conductive area for electrical and mechanical connections. Metallic contacts 182 and 186 are located on the first major surface 170 and provide conductive connection areas for the conductive paths 120 and 140 at the first major surface 170. Metallic contact 181 is located on the second major surface 175 and provides a conductive connection area for the conductive path 120 at the second major surface 175. As illustrated by metallic contacts 182 and 186, a metallic contact can substantially extend beyond the center of a conductive path to facilitate an electrical connection with, for example, a die coupled to the interposer 100. Metallic contact 187 is located on the second major surface 175 and is coupled to the ohmic contact region 160. In one embodiment, the metallic contacts 181, 182 and 186 are copper traces embedded on one of the respective major surfaces 170, 175. Conductive path 130 does not include a metallic contact on either the first major surface 170 or the second major surface 175. As such, the conductive path 130 can directly couple to a connector such as a microbump or a flip-chip bump. Similarly, conductive path 140 does not include a metallic contact at the first surface 170.

One skilled in the art will understand that the interposer 100 may include other conductive paths and metallic contacts. Additionally, FIG. 1 is a two-dimensional side view of interposer 100. As such, the various components of the interposer 100 are represented in two-dimensions in FIG. 1. However, one skilled in the art will understand that an interposer (and the components thereof) is a three-dimensional device. Accordingly, FIG. 2 illustrates a three-dimensional view of a conductive path in a semiconductor substrate of an interposer to provide more detail thereof.

The semiconductor substrate 110 can be any known semiconductor including but not limited to gallium arsenide, indium phosphide, germanium and silicon. The embodiments illustrated and described herein are a silicon substrate. One skilled in the art would know how to apply the teachings of this embodiment to embodiments in other semiconductors. In one embodiment, the silicon semiconductor substrate 110 may be a p-type substrate. In another embodiment, the silicon semiconductor substrate 110 may be an n-type substrate. As known in the art, a p-type semiconductor substrate has an excess of holes compared to an n-type region and an n-type semiconductor substrate has an excess of free electrons compared to a p-type region.

The conductive paths 120, 130, and 140, together with metallic contacts, are configured to provide conductive signal paths through silicon substrate 110, for electrically coupling dies, for providing electrical connections to other IC components or to provide structures that can mechanically secure dies, or die and other components, together. Unlike metal wires in a system-on-a-chip (SoC) which are embedded in dielectrics (such as SiO₂ or low-K), the metal within conductive paths 120, 130, 140 are embedded in a semiconductor, the semiconductor substrate 110.

Each of the conductive paths 120, 130 and 140, is a vertical, cylindrical aperture etched in the semiconductor substrate 110 and includes a conductive material and an associated oxide layer. Conductive materials include but are not limited to being a metal. The conductive paths 120, 130 and 140 completely extend through the height of the semiconductor substrate 110 and therefore are referred to as through conductive apertures (e.g., a through silicon via (TSV)). As such, the height of the conductive paths 120, 130 and 140 is substantially the same as the height of the semiconductor substrate 210. As illustrated in FIG. 4 and FIG. 5, in some embodiments an interposer includes conductive paths that do not include a through conductive aperture. Instead, these conductive paths include at least two conductive apertures that do not completely extend through the height of a semiconductor substrate. As such, these types of conductive apertures are referred to herein as partial conductive apertures. In these embodiments, at least two partial conductive apertures are coupled together by a metallic interconnect to provide a conductive path through an interposer. FIG. 4 provides an example of conductive paths including two partial conductive apertures connected by a metallic interconnect.

Conductive path 120 includes conductive material 122 and oxide layer 124. Conductive paths 130 and 140 include conductive material 132, 142, and oxide layers 134, 144, respectively. The conductive material 122 is connected to metallic contact 182 and 181 to provide electrical and mechanical contact areas for the conductive path 120 at the first major surface 170 and the second major surface 175. The conductive material 142 is connected to metallic contact 186 to provide an electrical and mechanical contact area for the conductive path 140 at the first major surface 170.

In addition to the conductive material and oxide layers, when a voltage is applied to the conductive material of the conductive paths 120, 130, and 140, a depletion region around the respective conductive paths is formed. The depletion region for each of the conductive paths 120, 130 and 140, as denoted by the dashed lines in FIG. 1, are 128, 138 and 148, respectively. Conductive path 120 is typical and will be discussed in more detail below.

The conductive material 122 is isolated electrically from the semiconductor substrate 110 by the use of the oxide layer 124. In one embodiment, the oxide layer 124 is a thin layer of SiO₂. The depletion region 128, sometimes referred to as a depletion layer, is common in a semiconductor, such as silicon, and effectively acts as a dielectric. As further discussed with respect to FIG. 2, a depletion region of a conductive aperture is a substantially cylindrical shell having a width that extends from the outer radius R of a cylindrical shell formed by an associated oxide layer. The width of the depletion region 128 depends on a voltage associated with the conductive path 120, such as a voltage applied to the conductive material 122, and characteristics of the semiconductor substrate 110. As disclosed herein, a bias voltage applied to semiconductor substrate 110, known as a back bias voltage, is used to increase the width of the depletion region 128 and thereby reduce the capacitance associated with the depletion region 128. The width of the depletion region 128 is denoted in FIG. 1 as the thickness, T_{DR}. T_{DR}, therefore, is dependent on the magnitude of the voltage applied to the conductive material 122, the magnitude of the back bias voltage applied to the semiconductor substrate 110 and characteristics of the semiconductor substrate 110. The height of depletion region 128 is the height of the conductive material 122 which, with conductive path 120, is substantially the height of the silicon substrate 110.

The voltage applied to the conductive material 122 is the voltage of the signal applied thereto. When the signal traverses the conductive material 122, the associated voltage causes the depletion region 128 to be formed. By applying the back bias voltage to the semiconductor substrate 110, the width of the depletion region 128 can be increased. As such, the capacitance associated with the depletion region 128 is decreased. In some embodiments, the magnitude of the applied back bias voltage increases the width, or volume, of adjacent depletion regions such that they meet and form fully depleted regions. For example, FIG. 1 illustrates partially depleted regions wherein adjacent depletion regions do not meet. With fully depleted regions, the dashed lines representing depletion region 138 would touch the dashed lines representing depletion regions 128 and 148.

The capacitance variation due to the presence of the depletion region may be represented by equation 1:

C=Cₒₓ/(1+(2Cₒₓ²V_{g}/∈ₛᵢqNₐ))^{1/2}. (Equation 1)

Where:
Cₒₓ is the capacitance of the oxide layer 124,
V_{g} is the voltage applied to the conductive path 120, Na is the doping level of the silicon of the semiconductor substrate 110,
q is the charge of an electron; and
∈ₛᵢ is the permittivity of silicon of the semiconductor substrate 110. Equation 1 can be modified to take into account the effect of a bias voltage applied to the semiconductor substrate 110 as represented by equation 2:

C=Cₒₓ/(1+(2Cₒₓ²(V_{g}+φ_{b})/∈ₛᵢqNₐ)^{1/2}. (Equation 2)

Where:
φb is a back bias voltage applied to the semiconductor substrate 110 of the interposer 100 according to the principles of the disclosure. For a p-type semiconductor substrate 110, (i.e., a commonly used ‘P’ doped silicon substrate), the applied back bias voltage is negative in order to increase the depletion region and thus reduce the depletion capacitance. For an n-type semiconductor substrate 110, (i.e., a commonly used ‘N’ doped silicon substrate), the applied back bias voltage is positive in order to increase the depletion region and thus reduce the depletion capacitance.

A back bias voltage source is used to supply the back bias voltage to the semiconductor substrate 110 via the ohmic contact region 160. As illustrated in the embodiments of FIG. 3 and FIG. 4, the back bias voltage source can be an external voltage source that is not included within dies coupled to an interposer, or an on-chip voltage source that is included within a die coupled to an interposer. The ohmic contact region 160 receives the back bias voltage through metallic contact 187. A conventional connector (not illustrated), such as a flip chip bump, wire bond or a ball grid array ball, is specifically positioned with the metallic contact 187 to provide an electrical path between a back bias voltage source and the ohmic contact region 160.

The ohmic contact region 160 is a low resistance contact area configured to receive the back bias voltage to reverse bias the semiconductor substrate 110. The ohmic contact region 160 is highly doped to provide the low resistance contact. For a p-type semiconductor substrate, the ohmic contact region 160 is a highly doped P+ region. For n-type semiconductor substrates, the ohmic contact region 160 would be a highly doped N+ region. The range of doping densities for the N+ and P+ regions may be in the range of 1E18 to 1E21 per cm³. An ohmic contact region can be included on both of the major surfaces 170, 175, of semiconductor substrate 110 or on either of the major surfaces 170, 175, of semiconductor substrate 110.

FIG. 2 illustrates a diagram of an embodiment of a conductive path 200. The conductive path 200 is a through conductive aperture that extends through the height of a semiconductor substrate 210. The depletion region properties described herein of conductive aperture 200, however, also apply to a partial conductive aperture. Additionally, one skilled in the art will understand that the depletion region properties described herein extend to metallic interconnects of a conductive path with respect to the geometry of the metallic interconnects. The semiconductor substrate 210 is part of an interposer capable of being reverse biased, such as interposer 100. As with the semiconductor substrate 110, the semiconductor substrate 210 can be any known semiconductor.

Conductive path 200 is a vertical, cylindrical aperture etched in the semiconductor substrate 210. The semiconductor material that remains after the etching step forms a substantially cylindrical wall 202 that defines the outer surface of the conductive path 200. The cylindrical wall 202 has a radius of R. The conductive path 200 includes an oxide layer 220 and a conductive material 230. Associated with the conductive path 200 are metallic contacts 212 and 214.

The oxide layer 220 is typically grown on the cylindrical wall 202, using a known process, to a thickness of T, with the oxide forming the oxide layer 220 that is shaped substantially as a cylindrical shell extending inwardly from cylindrical wall 202. The cylindrical shell has an outer radius of R and an inner radius of R less the thickness of oxide layer 220, T. The height of the cylindrical shell is substantially the height, H, of the substrate 210.

The cylindrical shell formed by oxide layer 220 is filled in a subsequent processing step with the conductive material 230. Conductive materials include but are not limited to being a metal, such as copper or tungsten. The conductive material 230 forms a substantially cylindrical shape to fill the cylindrical shell formed by oxide layer 220. The resulting substantially cylindrical conductive material 230 has an outer radius of R-T, which is the same as the inner radius of the cylindrical shell formed by oxide layer 220, absent any intervening layers. The height of the substantially cylindrical conductive material 230 is the height, H, of the silicon substrate 210.

The conductive material 230 is coupled to metallic contacts 212 and 214 on major surfaces 216 and 218, respectively, as is known in the art. Some interposers will have identical metallic contacts 212 or 214 on both major surfaces 216 and 218 of semiconductor substrate 210, and others will have different metallic contacts 212 or 214 on both major surfaces 216 and 218 of semiconductor substrate 210. If conductive path 200 represents a partial conductive aperture, metallic contact 212 is a metallic interconnect that provides interconnection to other metallic conductors such as are formed in layers of an integrated circuit to provide signal path routing to, for example, another partial conductive aperture and a different location on a major surface of an interposer.

As noted above, when a voltage is applied to the conductive material 230 the depletion region 240 is formed in the semiconductor substrate 210. The depletion region 240 is formed in the semiconductor substrate 210 surrounding wall 202, and hence surrounding oxide layer 220. Depletion region 240 is a substantially cylindrical shell having an inner radius of R, which is the same as the radius of both wall 202 and the outer radius of the cylindrical shell formed by oxide layer 220, and has an outer radius of R+T_{DR}. The outer radius R+T_{DR} is dependent on the magnitude of a back bias voltage applied to the semiconductor substrate 210, and characteristics of the semiconductor substrate 210. The height of depletion region 240 is substantially the height of the conductive material 230.

FIG. 3 illustrates a graph representing the reduction of relative capacitance associated with a conductive path when employing a back bias voltage according to the principles of the disclosure. For FIG. 3, the conductive path is a through conductive aperture. FIG. 3 represents a p-type semiconductor silicon substrate with Na=1E14/cm3 and a negative back bias voltage. The graph of FIG. 3 plots the associated relative capacitance versus the applied back bias voltage. The x-axis represents the back bias voltage applied to the semiconductor substrate of an interposer and the y-axis represents the relative capacitance associated with a conductive path. The relative capacitance is normalized to Vg=0 for the zero back bias voltage case. Two different examples are represented in the graph. The first example is for a back bias voltage of zero volts. The second example is for a back bias voltage of 0.9 volts. As illustrated in FIG. 3, as much as a 40% reduction in conductive path relative capacitance can be achieved with an applied back bias voltage of 0.9 volts.

FIG. 4 illustrates a cross-section view of an embodiment of a 3D IC 400. The 3D IC includes a heat sink 410, a first die 420, an interposer 430 capable of being reverse biased, a second die 440 and an IC substrate 450. The interposer 430 is connected to the first die 420 and the second die 440 by reflowed microbumps 460. The interposer 430 is also connected to the IC substrate 450 by reflowed flip-chip bumps 462. A ball grid array 464 is illustrated for connecting the IC substrate 450 to another board, component, or similar device. An underfill 466 is also illustrated in the space between the interposer 430 and the first die 420 as well as between the interposer 430 and second die 440. The reflowed microbumps 460, the reflowed flip-chip bumps 462, the ball grid array 464 and the underfill 466 may be common components that are typically used in 3D IC configurations. The heat sink 410 and the IC substrate 450 may also be common components that are typically used in 3D IC configurations.

The first die 420 and the second die 440 are two functional dies that are electrically and mechanically coupled together by the interposer 430. In FIG. 4, the first die 420 is a logic die and the second die 440 is a memory die. In one embodiment, the first die 420 can be a core logic die with input and output functionality and the second die 440 may be an eDRAM. The first die 420 and the second die 440 can be conventional functional dies that are typically employed in a 3D IC.

As mentioned above, the interposer 430 is configured to connect signal pads on the first die to signal pads on the second die thereby providing both electrical and mechanical interconnections. The interposer 430 includes a semiconductor substrate 432, conductive paths 437 and an ohmic contact region 436. The semiconductor substrate 432 includes a first major surface 431 and a second major surface 433. The conductive paths 437 includes both through conductive apertures and partial conductive apertures that are connected together. Through conductive aperture 434 is specifically denoted. Additionally, one of the conductive paths 437 is denoted as conductive path 438 and includes partial conductive aperture 492, metallic interconnect 494 and partial conductive aperture 496.

The interposer 430 also includes metallic contacts, represented by metallic contact 435, that are located at the major surfaces of the semiconductor substrate 432 to provide contact area for external connections, such as to the reflowed flip-chip bumps 462. In FIG. 4, the metallic contacts are copper traces embedded in the major surfaces of the interposer 430. In FIG. 4, the semiconductor substrate 432 is a p-type substrate and therefore is doped with a P dopant. In other embodiments, the semiconductor substrate 432 may be n-type substrate with an N dopant. The conductive paths 437 are configured to provide electrical routes through the semiconductor substrate 432 to provide electrical connections, such as, for electrically connecting pads and circuits on the first die 420 to pads and circuits on the second die 440. To reduce confusion in FIG. 4, a single component may be denoted to represent multiple similar components. For example, each of the conductive paths 437 of the interposer 430 is not specifically called-out in FIG. 4.

The ohmic contact region 436 is a low resistance contact configured to receive the back bias voltage to reverse bias the semiconductor substrate 432 to increase a depletion region of the conductive paths 437. The ohmic contact region 436 is a highly doped region for making ohmic contacts. Since in the embodiment described with respect to FIG. 4, the semiconductor substrate 432 is a p-type substrate, the ohmic contact region 436 is a highly doped P+ region. For example, the ohmic contact region 436 may be a silicided contact to the p-type semiconductor substrate 432. An ohmic contact region can be included on both of major surfaces of semiconductor substrate 432 or on either of the major surfaces of semiconductor substrate 432. For n-type substrates, the ohmic contact region 436 would be a highly doped N+ region. The range of doping densities for the N+ and P+ regions may be in the range of 1E18 to 1E21 per cm³. The ohmic contact region 436 is highly doped to provide a low resistance contact.

Though not illustrated in FIG. 4, the interposer 430 may include multiple ohmic contact regions such as the ohmic contact region(s) 436. It is noted that current supply required to bias the interposer 430 to the required negative voltage is typically very small, as leakage currents through the oxide lining of the conductive paths 437 wall can be negligible. Due to the low current requirements typically needed for biasing, in other embodiments, the ohmic contact region 436 can be placed along the periphery of the interposer 430 as shown in FIG. 6. The biasing voltage can range from 0 to 2V. The dielectric thickness insulating the conductive paths 437 from the surrounding semiconducting substrate is typically in the range of 0.5 um-1.0 um. For such thicknesses, the total leakage current, due to applying a back bias voltage to the semiconductor substrate, for an entire chip is expected to be less than 1 pA. Unlike a conventional interposer, additional processing (doping in designated areas) will be needed during manufacturing of the semiconductor substrate 432 to establish the ohmic contact region 436 or multiple thereof.

The 3D IC 400 also includes an off-chip back bias voltage source 470 that is configured to supply or generate the back bias voltage. The off-chip back bias voltage source 470 is an external voltage source that is not part of the first die 420 or the second die 440 in this embodiment. The off-chip back bias voltage source 470 may be a voltage regulator from the test board on which the chip resides.

The off-chip back bias voltage source 470 is connected to the interposer 430 through a dedicated interconnect 474 as illustrated in FIG. 4. The dedicated interconnect 474 is illustrated as a flip chip bump that is connected to the interposer 430 at metallic contact 476. The metallic contact 476 is used to couple the dedicated interconnect 474 to the ohmic contact region 436. An additional ball grid array 464 is also be used to couple the off-chip back bias voltage source 470 to the IC substrate 450 for connecting to the interposer 430.

FIG. 5 illustrates a cross-section view of another embodiment of a 3D IC 500. The 3D IC 500 includes a heat sink 510, a first die 520, an interposer 530 capable of being reverse biased, a second die 540 and an IC substrate 550. The interposer 530 is connected to the first die 520 and the second die 540 by reflowed microbumps 560. The interposer 530 is also connected to the IC substrate 550 by reflowed flip-chip bumps 562. A ball grid array 564 is illustrated for connecting the IC substrate 550 to another board, component, or similar device. An underfill 566 is also illustrated in the space between the interposer 530 and the first die 520 as well as between the interposer 530 and second die 540. The reflowed microbumps 560, the reflowed flip-chip bumps 562, the ball grid array 564 and the underfill 566 may be common components that are typically used in 3D IC configurations. The heat sink 510 and the IC substrate 550 may also be common components that are typically used in 3D IC configurations.

The 3D IC 500 includes a back bias voltage source 570 that is on-chip (i.e., included within a die coupled to the interposer being biased such as the first die 520 or the second die 540). In this embodiment, the first die 520 includes the back bias voltage source 570 that is connected to an ohmic contact region 536 of the semiconductor substrate 532 of the interposer 530 by a dedicated interconnect 574 through a metallic contact 576. The illustrated dedicated interconnect 574 is a microbump, but is not limited thereto. Additional underfill may also be added and extended to the dedicated bump connector 574. The back bias voltage source 570 may be a suitable voltage generator such as a charge pump or an on-chip voltage-regulator circuit embedded within the first die 520. Such circuits can be configured to provide a range of output voltages with desired tolerance and current supply limits. In one embodiment, the magnitude of the back bias voltage is selected based on a desired or required capacitance reduction.

FIG. 6 illustrates a top view of an embodiment of the interposer 430. The top view of the interposer 430 illustrates that multiple ohmic contact regions 436 may be located on the periphery of the interposer 430. In FIG. 6, each of the ohmic contact regions 436 are aligned with a reflowed flip-chip bump 462. This corresponds to the ohmic contact region 436 and the dedicated interconnect 474 of FIG. 4. An interposer may be constructed with multiple ohmic contact regions. Not all of the ohmic contact regions, however, need to be coupled to a back bias voltage source for biasing the semiconductor substrate since, as stated previously, the static voltage drops across an interposer are expected to be small due to the minimal currents flowing across the interposer semiconductor substrate. Thus, an interposer can have multiple ohmic contact regions but a single applied back bias voltage. Not all of the ohmic contact regions need be connected to a back bias voltage source depending on how robust the connection is and how high the leakage currents are. The higher the leakage currents, more the need to have multiple contacts.

FIG. 7 illustrates a flow diagram of a method 700 of reducing capacitance associated with conductive apertures of an interposer carried according to the principles of the disclosure. The method begins in a step 705.

In step 710, a back bias voltage is generated to reverse bias a semiconductor substrate of an interposer for increasing a depletion region of conductive apertures of the interposer. A voltage source on a die coupled to the interposer may be used to generate the back bias voltage. In another embodiment, the generating may be from a voltage source that is external to dies directly connected to the interposer. A die that is directly connected to the interposer does not have another component coupled therebetween. The first and second die of FIG. 4 or FIG. 5 are examples of directly connected dies.

The back bias voltage may be a negative voltage or could be a positive voltage. The polarity of the voltage depends on the type of dopant used with the interposer. For example, if the interposer is a p-type interposer, then a negative voltage would be applied. For an n-type interposer, a positive voltage would be applied.

The generated back bias voltage is applied to the interposer via an electrical path, such as a dedicated interconnect, in a step 720. The type of dedicated bump connector may depend on if the voltage source is external of a die coupled to the interposer (i.e., on-chip). If on a die, the coupled die may be directly coupled to the interposer by microbumps. In this embodiment, a dedicated microbump is employed to connect the voltage source of the die to the interposer. In another embodiment with an external voltage source, a dedicated flip chip bump can be used to couple the voltage source to the interposer for supplying the back bias voltage.

The magnitude of the back bias voltage generated and applied to the interposer can be varied to obtain a desired width T_{DR} of the depletion regions around the conductive apertures. In some embodiments, the magnitude of the back bias voltage provides fully depleted regions. Fully depleted regions occur when the conductive apertures are close enough that a large enough voltage can be applied to make sure that the depletion regions around each conductive aperture touch each other. In other embodiments, the magnitude of the back bias voltage provides partially depleted regions wherein the adjacent depletion regions do not touch. The dashed lines of FIG. 1 represent partially depleted regions. For fully depleted regions, the dashed lines of depletion region 138 would touch the dashed lines of adjacent depletion regions 128 and 148. A fully depleted situation gives rise to significant advantages over partially depleted. It has been shown that one of the significant advantages of a fully depleted substrate around the conductive apertures is the relatively low loss (higher integrity) of a high frequency signal passing through the conductive apertures. The voltage required to achieve such a situation is calculated using basic equations for depletion region estimation that have been used to derive Equation 2. The method 700 ends in a step 730.

FIG. 8 illustrates a flow diagram of an embodiment of a method 800 for manufacturing a interposer capable of being reverse biased. The method begins in a step 805.

In a step 810, a doped semiconductor substrate of an interposer is provided. The doped semiconductor substrate includes at least one conductive path such as a through conductive aperture. The doped semiconductor substrate can be any known doped semiconductor including but not limited to gallium arsenide, indium phosphide, germanium and silicon. In one embodiment, the doped semiconductor substrate is a p-type silicon substrate. In another embodiment, the doped semiconductor substrate is an n-type silicon substrate. Provided or providing is defined herein as being made in-house by a manufacturer or being obtained from another source such as a third party vendor.

A region of the doped semiconductor substrate is heavily doped to form an ohmic contact region in a step 820. The ohmic contact region is highly doped to provide a low resistance contact area for the interposer. For a p-type semiconductor substrate, the ohmic contact, region is a highly doped P+ region. For n-type semiconductor substrates, the ohmic contact region is a highly doped N+ region. The range of doping densities for the N+ and P+ regions can be in the range of 1E18 to 1E21 per cm³. In some embodiments, multiple ohmic contact regions are formed in the doped semiconductor substrate. An ohmic contact region can be included on both of the major surfaces of the doped semiconductor substrate or on either of the major surfaces of the doped semiconductor substrate. In one embodiment, the ohmic contact region or regions are formed using conventional doping procedures.

In a step 830, a metallic contact is formed near the surface of the semiconductor substrate and in contact with the ohmic contact region. In some embodiments, multiple metallic contacts are formed to correspond to the number of ohmic contact regions that are formed. In one embodiment, the metallic contact or contacts are formed by conventional procedures. The method 800 ends in a step 830.

Those skilled in the art to which this application relates will appreciate that other and further additions, deletions, substitutions and modifications may be made to the described embodiments.

What is claimed is:

1. An interposer capable of being reverse biased, comprising:
a semiconductor substrate that is doped with a dopant;
conductive paths located within said semiconductor substrate and configured to provide electrical routes therethrough; and
an ohmic contact region located within said semiconductor substrate and configured to receive a back bias voltage.

2. The interposer as recited in claim 1 wherein said ohmic contact region has a dopant concentration higher than a dopant concentration of said semiconductor substrate.

3. The interposer as recited in claim 1 wherein said interposer includes multiple ohmic contact regions.

4. The interposer as recited in claim 3 wherein each of said multiple ohmic contact regions is located along a periphery of said interposer.

5. The interposer as recited in claim 1 wherein said dopant is a P dopant and said back bias voltage is a negative back bias voltage.

6. The interposer as recited in claim 1 wherein said dopant is an N dopant and said back bias voltage is a positive back bias voltage.

7. The interposer as recited in claim 1 wherein said depletion region is a partial depletion region.

8. A method of reducing capacitance associated with conductive paths within a semiconductor substrate of an interposer capable of being reverse biased, comprising:
generating a back bias voltage to reverse bias said semiconductor substrate to increase a depletion region therein that is associated with at least one of said conductive paths; and
applying said back bias voltage to said interposer through an electrical contact.

9. The method as recited in claim 8 wherein said generating is performed on a die connected to said interposer.

10. The method as recited in claim 8 wherein said generating is performed external to said interposer and die connected thereto.

11. The method as recited in claim 8 wherein said electrical contact is a microbump.

12. The method as recited in claim 8 wherein said electrical contact is coupled to an ohmic contact region of said semiconductor substrate.

13. The method as recited in claim 8 wherein said back bias voltage is a negative voltage.

14. The method as recited in claim 8 wherein said depletion region is formed in said semiconductor substrate by a voltage from a signal applied to said at least one of said conductive paths.

15. A three dimensional integrated circuit, comprising:
a first die;
a second die; and
an interposer capable of being reversed bias located between said first and said second die and configured to connect said first die to said second die, said interposer including:
a semiconductor substrate that is doped with a dopant;
conductive paths located within said semiconductor substrate and configured to provide electrical routes through said semiconductor to connect said first die to said second die; and
an ohmic contact region located within said semiconductor substrate and adapted to be coupled to a back bias voltage source.

16. The three dimensional integrated circuit as recited in claim 15 wherein said first die includes said voltage source.

17. The three dimensional integrated circuit as recited in claim 15 wherein said voltage source is external to said three dimensional integrated circuit.

18. The three dimensional integrated circuit as recited in claim 15 wherein said interposer includes multiple ohmic contact regions, wherein each of said multiple ohmic contact regions is located along a periphery of said interposer and has a dopant concentration higher than a dopant concentration of said semiconductor substrate.

19. The three dimensional integrated circuit as recited in claim 15 further comprising an electrical contact to couple said voltage source to said ohmic contact region.

20. The three dimensional integrated circuit as recited in claim 15 wherein said back bias voltage is a negative voltage.

21. A method of manufacturing an interposer capable of being reversed biased, comprising:
providing a doped semiconductor substrate of an interposer, said doped semiconductor substrate including at least one conductive path;
heavily doping a region of said doped semiconductor substrate to form an ohmic contact region; and
forming a metallic contact near a surface of said doped semiconductor substrate in electrical contact with said ohmic contact region.
